(19) United States
(12) Patent Application Publication
(10) Pub. No.: US 2026/0123313 A1
(43) Pub. Date: Apr. 30, 2026

(54) Subtractive Metal flow with Tip-to-Tip Critical Dimension Reduction

(71) Applicant: Applied Materials, Inc., Santa Clara, CA (US)

(72) Inventors: Yung-Chen Lin, Westwood, MA (US); Shurong Liang, Lynnfield, MA (US); Steven Sherman, Newton, MA (US); Huixiong Dai, San Jose, CA (US)

(73) Assignee: Applied Materials, Inc., Santa Clara, CA (US)

(21) Appl. No.: 18/925,695

(22) Filed: Oct. 24, 2024

(51) Int. Cl. H01L 21/3213; H01L 21/02; H01L 21/033

(52) U.S. Cl. CPC H10P 50/267; H10P 14/6922; H10P 50/71; H10P 76/405

(57) ABSTRACT

A method may include providing a first hardmask and a second hardmask over a metal line layer, wherein the metal line layer is formed over a dielectric layer, and forming a plurality of trenches through the first hardmask and the second hardmask, wherein each of the plurality of trenches is defined by a first main side opposite a second main side, and a first end opposite a second end. The method may further include performing a plasma etch to remove a portion of the first hardmask and the second hardmask from the first end or the second end of each of the plurality of trenches, wherein the plasma etch comprises directing ions into the plurality of trenches at a non-zero angle relative to a perpendicular extending from an upper surface of the second hardmask.

### Field of the Disclosure

The present embodiments relate to semiconductor device patterning and, more particularly, to a subtractive metal process flow with tip-to-tip critical dimension reduction.

### Background of the Disclosure

Semiconductor fabrication techniques often use photoresist masking and plasma etching to form metal structures. Back-End-Of-Line (BEOL) processing, for example, is used to create interconnections including the metal structures. In scaled technology nodes (e.g., 10 nanometer or less), tight tip-to-tip critical dimension to improve line-end metal-to-via enclosure is required. Accordingly, improved approaches are needed for tip-to-tip critical dimension reduction during subtractive metal processing.

### Summary

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In one aspect, a method may include providing a first hardmask and a second hardmask over a metal line layer, wherein the metal line layer is formed over a dielectric layer, and forming a plurality of trenches through the first hardmask and the second hardmask, wherein each of the plurality of trenches is defined by a first main side opposite a second main side, and a first end opposite a second end. The method may further include performing a plasma etch to remove a portion of the first hardmask and the second hardmask from the first end or the second end of each of the plurality of trenches, wherein the plasma etch comprises directing ions into the plurality of trenches at a non-zero angle relative to a perpendicular extending from an upper surface of the metal line layer.

In another aspect, a method of patterning a metal line layer may include providing a first hardmask and a second hardmask over the metal line layer, wherein the metal line layer is formed over an interlayer dielectric, and forming a plurality of trenches through the first hardmask and the second hardmask. Each of the plurality of trenches is defined by a first main side opposite a second main side, a first end opposite a second end, wherein the first and second ends connect with the first and second main sides, and an upper surface of the metal line layer. The method may further include performing a plasma etch to remove a portion of the first hardmask and the second hardmask from the first end and the second end of each of the plurality of trenches, wherein the plasma etch comprises directing ions into the plurality of trenches at a non-zero angle relative to a perpendicular extending from the upper surface of the metal line layer.

In yet another aspect, a method of patterning a metal line layer may include providing a first hardmask and a second hardmask over the metal line layer, wherein the metal line layer is formed over an interlayer dielectric, and forming a plurality of trenches through the first hardmask and the second hardmask. Each of the plurality of trenches may be defined by a first main side opposite a second main side, a first end opposite a second end, wherein the first and second ends connect with the first and second main sides, and an upper surface of the metal line layer. The method may further include performing a plasma etch to remove a portion of the first hardmask and the second hardmask from the first end and the second end of each of the plurality of trenches, wherein the plasma etch comprises directing ions into the plurality of trenches at a non-zero angle relative to a perpendicular extending from the upper surface of the metal line layer, and wherein the plasma etch does not remove the first hardmask or the second hardmask along the first main side and the second main side of each of the plurality of trenches. The method may further include forming a second plurality of trenches through the metal line layer after the plasma etch.

### Brief Description of the Drawings

The accompanying drawings illustrate exemplary approaches of the disclosure, including the practical application of the principles thereof, as follows:

FIG. 1A is a top view of a device structure including a plurality of trenches formed in a first hardmask and a second hardmask, according to embodiments of the present disclosure;

FIG. 1B is a side cross-sectional view, along cutline X-X’ of FIG. 1A, illustrating the device structure, according to embodiments of the present disclosure;

FIG. 2A is a top view of a device structure according to embodiments of the present disclosure;

FIG. 2B is a side cross-sectional view, along cutline Y-Y’ of FIG. 1A, illustrating the device structure during a plasma etch process, according to embodiments of the present disclosure;

FIG. 3A is a top view of a device structure following a plasma fill and planarization process, according to embodiments of the present disclosure;

FIG. 3B is a side cross-sectional view, along cutline X-X’ of FIG. 3A, illustrating the device structure, according to embodiments of the present disclosure;

FIG. 4A is a top view of a device structure following removal of the first hardmask, according to embodiments of the present disclosure;

FIG. 4B is a side cross-sectional view, along cutline X-X’ of FIG. 4A, illustrating the device structure, according to embodiments of the present disclosure;

FIG. 5A is a top view of a device structure following formation of a plurality of trenches in a metal line layer, according to embodiments of the present disclosure;

FIG. 5B is a side cross-sectional view, along cutline X-X’ of FIG. 5A, illustrating the device structure, according to embodiments of the present disclosure;

FIG. 6 illustrates a schematic diagram of a processing apparatus according to embodiments of the present disclosure;

FIG. 7A illustrates an exemplary processing apparatus according to embodiments of the disclosure; and

FIG. 7B depicts details of an exemplary extraction plate according to embodiments of the disclosure.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of "slices", or "near-sighted" cross-sectional views, omitting certain background lines otherwise visible in a "true" cross-sectional view, for illustrative clarity. Furthermore, for clarity, some reference numbers may be omitted in certain drawings.

### Detailed Description

Methods and devices in accordance with the present disclosure will now be described more fully hereinafter with reference to the accompanying drawings, where various embodiments are shown. The methods and devices may be embodied in many different forms and are not to be construed as being limited to the embodiments set forth herein. Instead, these embodiments are provided so the disclosure will be thorough and complete, and will fully convey the scope of the methods to those skilled in the art.

Embodiments described herein advantageously provide increased device density by reducing tip-to-tip critical dimension (CD) during subtractive metal processing. More specifically, following trench formation through a plurality of hardmasks, an angled plasma etch is performed to enlarge the trenches along a single axis only. That is, the trenches may each include first and second main sides connected to first and second ends, wherein the etch removes hardmask material along the first and second ends without removing hardmask material along the first and second main sides. As a result, the ends of adjacent trenches are located closer to one another, thereby increase device density.

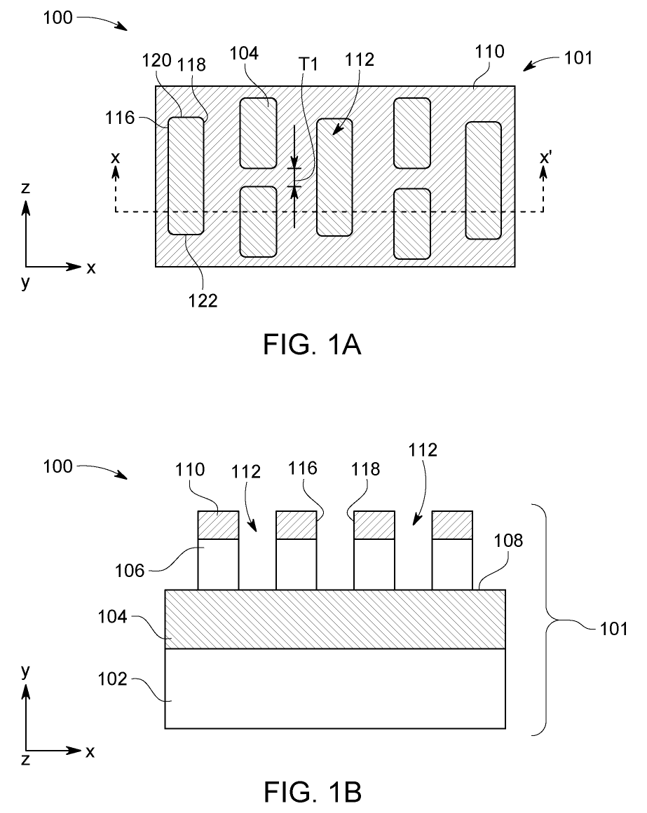

FIG. 1A is a simplified top view, and FIGS. 1B is a cross-sectional view along cutlines X-X’ of FIG. 1A, of a portion of a semiconductor device (hereinafter “device”) 100, according to one or more embodiments of the disclosure. The device 100 may include a device stack or structure 101 including a base dielectric layer 102 (e.g., interlayer dielectric), and a metal line layer 104 formed over the base dielectric layer 102. In various embodiments, the metal line layer 104 may be ruthenium (Ru), molybdenum (Mo), tungsten (W), or others.

The device structure 101 may further include a first hardmask 106 formed atop an upper surface 108 of the metal line layer 104, and a second hardmask 110 formed over the first hardmask 106. Although non-limiting, in various embodiments, the first hardmask 106 is one of: tungsten carbide (WC), amorphous silicon (a-Si), silicon nitride (SiN), and titanium nitride (TiN). Meanwhile, the second hardmask 110 may be an oxide or SiN. Other materials may be used in alternative embodiments. Furthermore, the first and second hardmasks 106, 110 may be deposited or otherwise formed using a variety of known techniques.

As further shown, the device 100 may include a plurality of trenches 112 formed through the first hardmask 106 and the second hardmask 110, wherein the plurality of trenches 112 extend to the upper surface 108 of the metal line layer 104. Each of the plurality of trenches 112 may be defined by a first main side 116 opposite a second main side 118, and a first end 120 opposite a second end 122. In the embodiment shown, the first and second main sides 116, 118 are longer/larger than the first and second ends 120, 122.

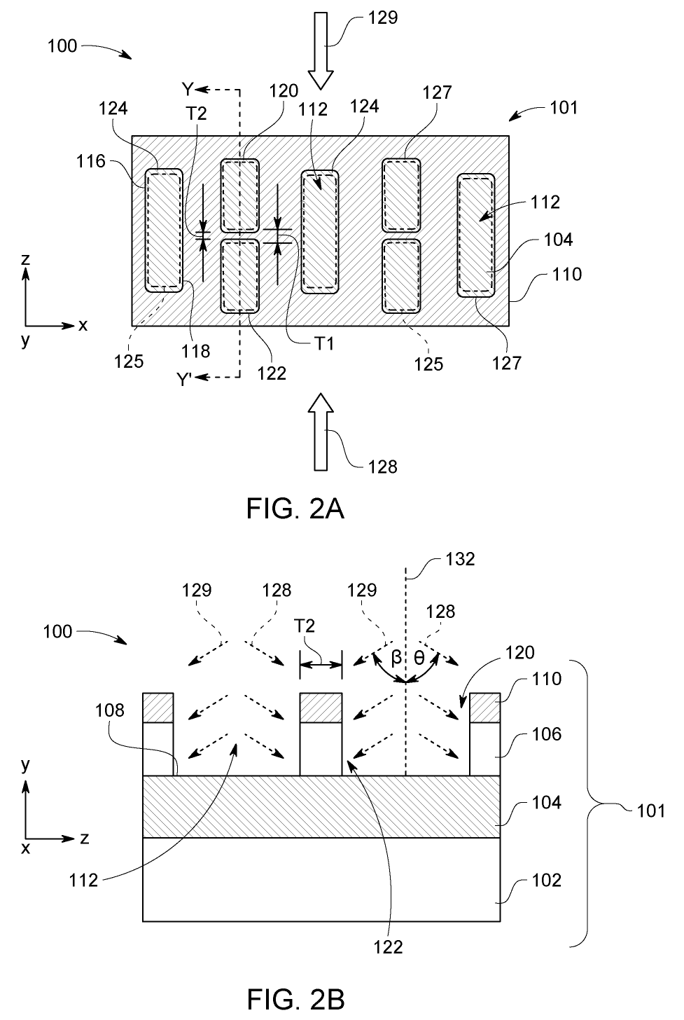

As shown in FIGS. 2A – 2B, a plasma etch process may then be performed to remove a portion 124 of the first hardmask 106 and the second hardmask 110 from the first end 120 and/or the second end 122 of each of the plurality of trenches 112. Said another way, each of the trenches 112 may be enlarged, e.g., in the z-direction, as a result of the etch process. A first perimeter 125, demonstrated by the broken line, corresponds to each trench 112 prior to the etch process. A second perimeter 127 corresponds to each trench 112 after the etch process. The difference between the first perimeter 125 and the second perimeter 127, in +/- z-directions, is the portion 124 removed using the plasma etch.

As better shown in FIG. 2B, the plasma etch process may include directing first ions 128 into the plurality of trenches 112 at a first non-zero angle (θ) relative to a perpendicular 132 extending from the upper surface 108 of the metal line layer 104. The first ions 128 may be directed into a sidewall of the first end 120 of each trench 112. The first ions 128 may generally impact an entire height of the sidewall to remove material from both the first hardmask 106 and the second hardmask 110 at the first end 120.

The plasma etch process may further include directing second ions 129 into the plurality of trenches 112 at a second non-zero angle (β) relative to the perpendicular 132 extending from the upper surface 108 of the metal line layer 104. The second ions 129 may be directed into a sidewall of the second end 122 of each trench 112, and may generally impact an entire height of the sidewall to remove material from both the first hardmask 106 and the second hardmask 110 at the second end 122. In various embodiments, the first ions 128 and the second ions 129 may include a combination of dilution gases, e.g., helium, argon, and xenon, and reaction gases, e.g., all CFx gases (e.g., a fluorine containing gas (NF3), or a chlorine containing gas (Clx)). Although non-limiting, the first non-zero angle and the second non-zero angle may be between 10-70° relative to the perpendicular 132. Following the plasma etch process, a first tip-to-tip distance (T1) of the original trenches 112 may be reduced/shortened, as shown by the second tip-to-tip distance (T2).

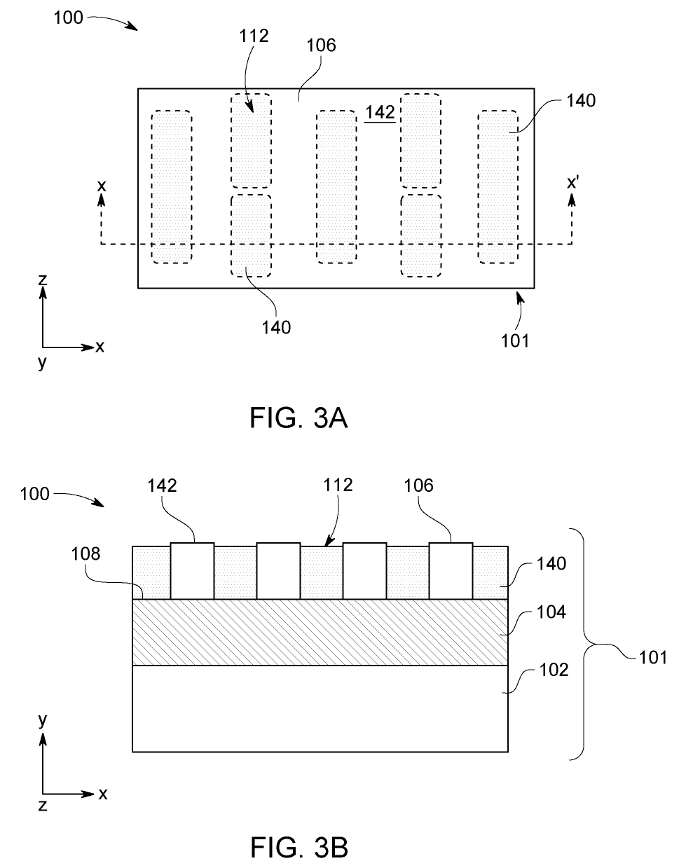

FIGS. 3A– 3B demonstrate the device 100 following formation of a fill material 140. In some embodiments, the fill material 140 may be one of oxide, silicon oxycarbide, silicon nitride, silicon carbide, or amorphous silicon, which is deposited over the device 100, including within each of the trenches 112. The fill material 140 may be formed directly atop the upper surface 108 of the metal line layer 104. The fill material 140 may then be partially removed (e.g., planarized) selective to an upper surface 142 of the first hardmask 106. As shown, the second hardmask 110 is removed as a result of the planarization process.

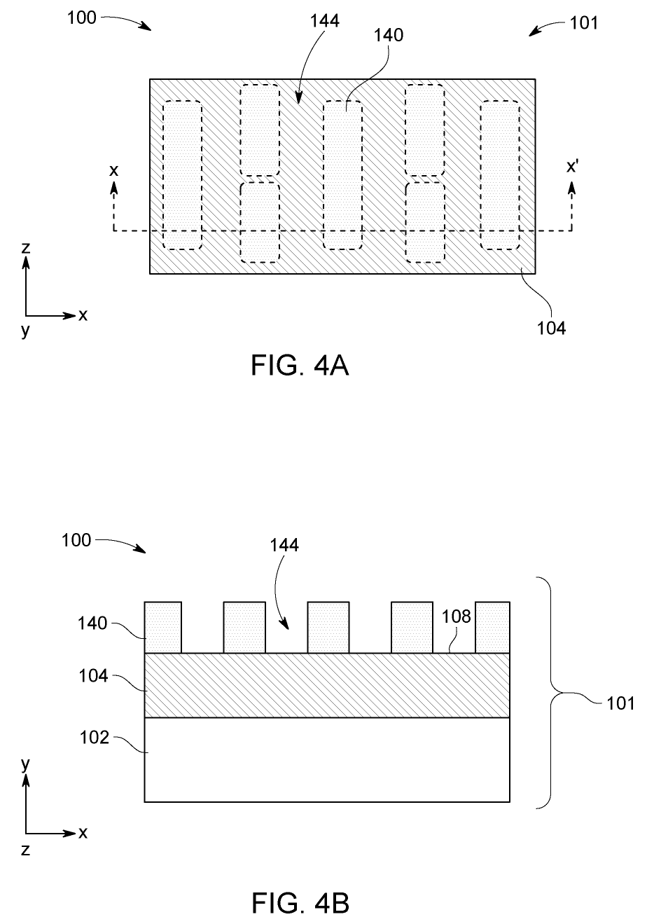

As shown in FIGS. 4A – 4B, the first hardmask 106 may then be removed to form a second plurality of trenches 144 between structures defined by the fill material 140. The first hardmask 106 may be removed selective to the upper surface 108 of the metal line layer 104 using a wet or dry etch process.

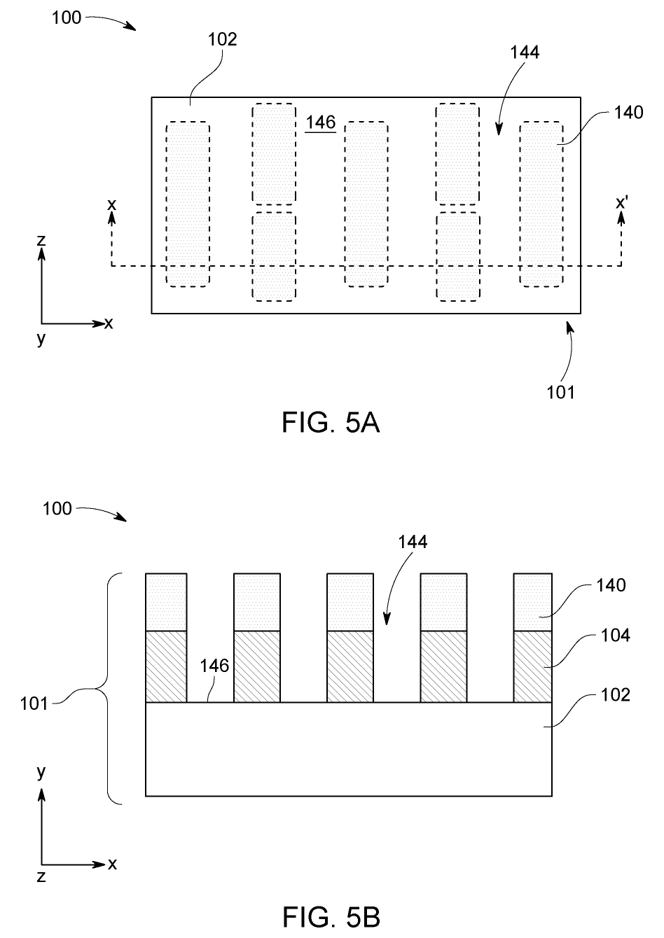

As shown in FIGS. 5A– 5B , the metal line layer 104 may then be partially removed by extending the second plurality of trenches 144 to an upper surface 146 of the base dielectric layer 102. In various embodiments, the metal line layer 104 may be removed using a wet or dry etch process. However, the etch parameters may be different than that of the etch process used to process the first hardmask 106.

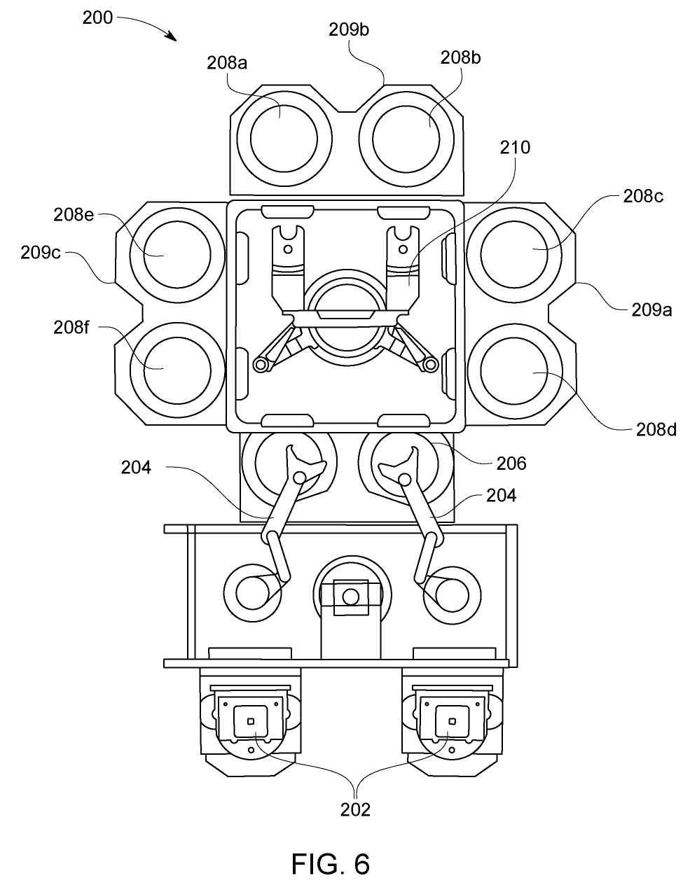

FIG. 6 illustrates a top plan view of a processing system 200 including a plurality of chambers according to some embodiments. As shown, a pair of front opening unified pods 202 supply substrates of a variety of sizes that are received by robotic arms 204 and placed into a low-pressure holding area 206 before being placed into one of the substrate processing chambers 208a-f, positioned in tandem sections 209a-c. A second robotic arm 210 may be used to transport the substrate wafers from the holding area 206 to the substrate processing chambers 208a-f and back. Each substrate processing chamber, 208a-f, can be outfitted to perform a number of substrate processing operations described herein such as ion implant, anneal, plasma processing (e.g., plasma etch), degas, orientation, and other substrate processes.

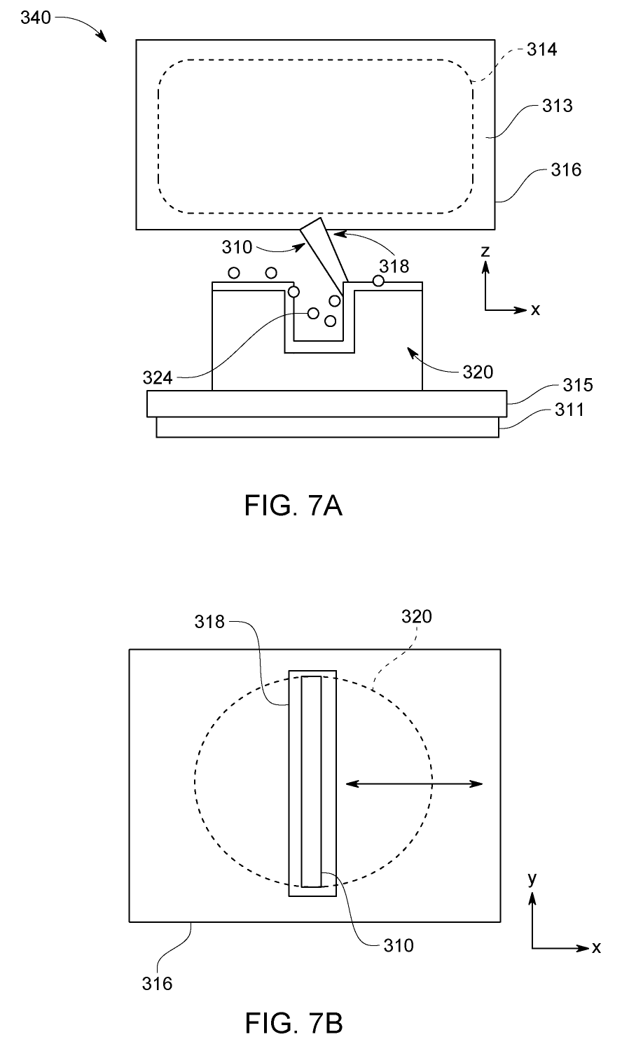

The substrate processing chambers 208a-f may include one or more system components for depositing, treating, growing, annealing, curing, implanting, and/or etching the substrate and/or a material layer on the substrate or wafer. In one configuration, two pairs of the processing chambers, for example 208a-b, may be used treat the substrate and/or the material layers formed atop the substrate using a beamline ion implant. Another two pairs of the processing chambers, for example, 208c-d, may be used to process the substrate and/or the material layers formed atop the substrate using a plasma etch process. More specifically, processing chambers 208c-d may include a compact plasma processing system 340, as shown in FIGS. 7A– 7B.

The system 340 may be operable to generate an ion beam shown as ions 310. The system 340 may be appropriate for performing one or more of the removal processes shown in FIGS. 2A– 2B, wherein ions 310 may be the same or similar to the first and second etching ions 128, 129 described in connection with these figures. More specifically, a substrate 320 (or stack of layers) may be exposed to reactive neutral species 324, where the reactive neutral species 324 are derived from precursor gas composition used to generate the RIE plasma. The reactive neutral species 324 may arrive to the substrate 320, where every portion of the different exposed surfaces of the substrate 320 are impacted by the reactive neutral species 324. Notably, the present embodiments harness the principles of RIE processing where etching of a given surface is enhanced in the presence of ions. Notably, in accordance with the present embodiments, etching may take place just in regions of the substrate 320 impacted by the directional ions, i.e., in regions impacted by the ions 310, while leaving other surfaces unetched.

The ion beam may be extracted from a plasma 314 generated in a plasma chamber 313 by any known technique. The system 340 may include an extraction plate 316 having an extraction aperture 318, where the ions are extracted as an ion beam from the plasma 314 and directed to the substrate 320. As shown in FIG. 7B, the extraction aperture 318 may be elongated along the Y-axis, providing a ribbon ion beam extending, for example, over an entire substrate along the direction parallel to the Y-axis. In various embodiments, the substrate 320 may be disposed on a substrate holder 315 and scanned along the X-axis to provide coverage at different regions of the substrate 320 or over the entirety of the substrate 320. In other embodiments, the extraction aperture 318 may have a different shape such as a square or circular shape.

In some embodiments, the plasma chamber 313 may also serve as a deposition process chamber to provide material for depositing on the substrate 320 in the deposition operation preceding etching, such as the deposition of the film layer(s). The substrate holder 315 may further include a heater assembly 311 for selectively heating the substrate 320 to different temperatures in different regions within the X-Y plane for selectively changing the amount of depositing material or amount of material removal, as discussed above.

During an ion exposure, reactive species may be provided or created in the plasma chamber 313 and may also impinge upon the substrate 320. While various non-ionized reactive species may impinge upon all surfaces of substrate 320, including different surfaces in one or more of the trenches, etching may take place in areas impacted by the ions 310, as in known RIE processes, while little or no etching takes place in regions not impacted by ions 310.

In further embodiments, directional etching of ions may be performed by rotating a substrate within the X-Y plane to any desired angle. Thus, a trench feature may be oriented with its long axis at a 45-degree angle with respect to the Y-axis while a ribbon beam directed to the trench feature has its axis oriented along the Y-axis as in FIG. 7B.

In additional embodiments, by scanning the substrate 320 with respect to the ion beam, such as along the X-axis as generally shown in FIG. 7B, the possibility is afforded to vary a directed etch across the substrate 320 to achieve location-specific directional selectivity of etching, so features within a certain region may be altered to one extent while features in another region are not altered or are altered to a different extent or in a different fashion.

Referring again to FIG. 6, it will be appreciated that any one or more of the processes described may be carried out in additional chambers separated from the fabrication system shown in different embodiments. It will be appreciated that additional configurations of deposition, treating, growing, etching, annealing, and curing chambers for substrates and material layers are contemplated by the processing system. Additionally, any number of other processing systems may be utilized with the present technology, which may incorporate chambers for performing any of the specific operations. In some embodiments, chamber systems which may provide access to multiple processing chambers while maintaining a vacuum environment in various sections, such as the noted holding and transfer areas, may allow operations to be performed in multiple chambers while maintaining a particular vacuum environment between discrete processes.

For the sake of convenience and clarity, terms such as "top," "bottom," "upper," "lower," "vertical," "horizontal," "lateral," and "longitudinal" will be understood as describing the relative placement and orientation of components and their constituent parts as appearing in the figures. The terminology will include the words specifically mentioned, derivatives thereof, and words of similar import.

As used herein, an element or operation recited in the singular and proceeded with the word "a" or "an" is to be understood as including plural elements or operations, until such exclusion is explicitly recited. Furthermore, references to "one embodiment" of the present disclosure are not intended as limiting. Additional embodiments may also incorporating the recited features.

Furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

It is to be understood that the various layers, structures, and regions shown in the accompanying drawings are schematic illustrations. For ease of explanation, one or more layers, structures, and regions of a type commonly used to form semiconductor devices or structures may not be explicitly shown in a given drawing. This does not imply that any layers, structures, and/or regions not explicitly shown are omitted from the actual semiconductor structures.

While certain embodiments of the disclosure have been described herein, the disclosure is not limited thereto, as the disclosure is as broad in scope as the art will allow and the specification may be read likewise. Therefore, the above description is not to be construed as limiting. Instead, the above description is merely as exemplifications of particular embodiments. Those skilled in the art will envision other modifications within the scope and spirit of the claims appended hereto.

What is claimed is:

1. A method, comprising:
providing a first hardmask and a second hardmask over a metal line layer, wherein the metal line layer is formed over a dielectric layer;
forming a plurality of trenches through the first hardmask and the second hardmask, wherein each of the plurality of trenches is defined by a first main side opposite a second main side, and a first end opposite a second end; and
performing a plasma etch to remove a portion of the first hardmask and the second hardmask from the first end or the second end of each of the plurality of trenches, wherein the plasma etch comprises directing ions into the plurality of trenches at a non-zero angle relative to a perpendicular extending from an upper surface of the metal line layer.

2. The method of claim 1, wherein the plasma etch does not remove the first hardmask or the second hardmask from the first main side and the second main side of each of the plurality of trenches.

3. The method of claim 1, wherein the plurality of trenches are formed to the upper surface of the metal line layer.

4. The method of claim 1, wherein directing the ions into the plurality of trenches at the non-zero angle comprises delivering the ions into a sidewall of the first end or the second end of each of the plurality of trenches.

5. The method of claim 1, further comprising forming a fill material within each of the plurality of trenches.

6. The method of claim 5, further comprising removing the first hardmask and the second hardmask without removing the fill material.

7. The method of claim 6, further comprising forming a second plurality of trenches through the metal line layer after the first hardmask and the second hardmask are removed.

8. The method of claim 6, wherein the first hardmask is one of: tungsten carbide, amorphous silicon, and silicon nitride, wherein the second hardmask is one of: oxide, and silicon nitride, and wherein the fill material is one of: oxide, silicon oxycarbide, silicon nitride, silicon carbide, amorphous silicon.

9. The method of claim 1, wherein the plasma etch comprises at least one of the following dilution gases: helium, argon, and xenon, and wherein the plasma etch further comprises at least one of the following reaction gases: a fluorine containing gas, and a chlorine containing gas.

10. A method of patterning a metal line layer, comprising:
providing a first hardmask and a second hardmask over the metal line layer, wherein the metal line layer is formed over an interlayer dielectric;
forming a plurality of trenches through the first hardmask and the second hardmask, wherein each of the plurality of trenches is defined by:
a first main side opposite a second main side;
a first end opposite a second end, wherein the first and second ends connect with the first and second main sides; and
an upper surface of the metal line layer; and
performing a plasma etch to remove a portion of the first hardmask and the second hardmask from the first end and the second end of each of the plurality of trenches, wherein the plasma etch comprises directing ions into the plurality of trenches at a non-zero angle relative to a perpendicular extending from the upper surface of the metal line layer.

11. The method of claim 10, wherein the plasma etch does not remove the first hardmask or the second hardmask from the first main side and the second main side of each of the plurality of trenches.

12. The method of claim 10, wherein directing the ions into the plurality of trenches at the non-zero angle comprises delivering the ions into a sidewall of the first end or the second end of each of the plurality of trenches.

13. The method of claim 10, further comprising:
forming a fill material within each of the plurality of trenches following the plasma etch; and
removing the first hardmask and the second hardmask without removing the fill material.

14. The method of claim 13, further comprising forming a second plurality of trenches through the metal line layer after the first hardmask and the second hardmask are removed, wherein the fill material remains over the metal line layer while the second plurality of trenches are formed through the metal line layer.

15. The method of claim 13, wherein the first hardmask is one of: tungsten carbide, amorphous silicon, and silicon nitride, wherein the second hardmask is one of: oxide, and silicon nitride, and wherein the fill material is one of: oxide, silicon oxycarbide, silicon nitride, silicon carbide, amorphous silicon.

16. The method of claim 10, wherein the plasma etch comprises at least one of the following dilution gases: helium, argon, and xenon, and wherein the plasma etch further comprises at least one of the following reaction gases: a fluorine containing gas, and a chlorine containing gas.

17. A method of patterning a metal line layer, comprising:
providing a first hardmask and a second hardmask over the metal line layer, wherein the metal line layer is formed over an interlayer dielectric;
forming a plurality of trenches through the first hardmask and the second hardmask, wherein each of the plurality of trenches is defined by:
a first main side opposite a second main side;
a first end opposite a second end, wherein the first and second ends connect with the first and second main sides; and
an upper surface of the metal line layer; and
performing a plasma etch to remove a portion of the first hardmask and the second hardmask from the first end and the second end of each of the plurality of trenches, wherein the plasma etch comprises directing ions into the plurality of trenches at a non-zero angle relative to a perpendicular extending from the upper surface of the metal line layer, and wherein the plasma etch does not remove the first hardmask or the second hardmask along the first main side and the second main side of each of the plurality of trenches; and
forming a second plurality of trenches through the metal line layer after the plasma etch.

18. The method of claim 17, wherein directing the ions into the plurality of trenches at the non-zero angle comprises delivering the ions into an entire height of a sidewall of the first end or the second end of each of the plurality of trenches.

19. The method of claim 17, further comprising:
forming a fill material within each of the plurality of trenches following the plasma etch; and
removing the first hardmask and the second hardmask without removing the fill material, wherein the second plurality of trenches are formed through the metal line layer after the first hardmask and the second hardmask are removed, and wherein the fill material acts as a mask while the second plurality of trenches are formed through the metal line layer.

20. The method of claim 19, wherein the first hardmask is one of: tungsten carbide, amorphous silicon, and silicon nitride, wherein the second hardmask is one of: oxide, and silicon nitride, and wherein the fill material is one of: oxide, silicon oxycarbide, silicon nitride, silicon carbide, amorphous silicon.
